(19) United States
(12) Patent Application Publication
(10) Pub. No.: US 2026/0173648 A1
(43) Pub. Date: Jun. 18, 2026

(54) DISPLAY DEVICE, ELECTRONIC DEVICE, AND METHOD FOR FABRICATING THE SAME

(71) Applicant: Samsung Display Co., Ltd., Yongin-si (KR)

(72) Inventors: Hwi KIM, Yongin-si (KR); Ji Hee SON, Yongin-si (KR); Joon Gu LEE, Yongin-si (KR)

(21) Appl. No.: 19/312,010

(22) Filed: Aug. 27, 2025

(30) Foreign Application Priority Data
Dec. 16, 2024 (KR) 10-2024-0187531

(51) Int. Cl. H10K 50/16; H10K 59/12; H10K 59/80; H10K 71/60

(52) U.S. Cl. CPC H10K 50/166; H10K 59/1201; H10K 59/80518; H10K 59/879; H10K 71/60

(57) ABSTRACT

A display device includes: a substrate; a first electrode on the substrate; an emissive layer on the first electrode; an electron transport layer on the emissive layer; an electron injection layer on the electron transport layer; and a second electrode on the electron injection layer and containing silver (Ag), wherein the electron transport layer includes: a first electron transport layer; and a second electron transport layer on a surface of the first electron transport layer, wherein a surface of the second electron transport layer contacts the electron injection layer, and a refractive index of the second electron transport layer is greater than a refractive index of the first electron transport layer, and wherein the second electrode includes: a first sub-electrode containing silver (Ag); and a second sub-electrode located on the first sub-electrode and containing ytterbium (Yb) and/or magnesium (Mg).

### CROSS-REFERENCE TO RELATED APPLICATION

The present application claims priority to and the benefit of Korean Patent Application No. 10-2024-0187531, filed on Dec. 16, 2024, in the Korean Intellectual Property Office, the entire disclosure of which is incorporated herein by reference.

### BACKGROUND

### 1. Field

Aspects of some embodiments of the present disclosure relate to a display device, an electronic device, and a method for fabricating the same.

### 2. Description of the Related Art

As the information-oriented society evolves, consumer demand for display devices is ever increasing. Display devices may be flat panel display devices such as a liquid-crystal display device, a field emission display device, and a light-emitting display device. Light-emitting display devices may include an organic light-emitting display device including an organic light-emitting element, an inorganic light-emitting display device including an inorganic light-emitting element such as an inorganic semiconductor, and a micro-light-emitting display device including an ultra-small light-emitting element.

A light-emitting element generally emits light as holes supplied from an anode and electrons supplied from a cathode combine in end emissive layer formed between the anode and cathode to form excitons, and such excitons are stabilized. Light-emitting elements may have various characteristics, such as relatively wide viewing angle, relatively fast response speed, relatively thin thickness, and relatively low power consumption, and are therefore widely used in a variety of electrical and electronic devices, such as televisions, monitors and mobile phones. However, light-emitting elements may require high driving voltages to achieve high brightness required for displays or lighting due to their low luminous efficacy, which may shorten the lifespan of the elements.

The above information disclosed in this Background section is only for enhancement of understanding of the background and therefore the information discussed in this Background section does not necessarily constitute prior art.

### SUMMARY

Aspects of some embodiments of the present disclosure include a light-emitting element with relatively improved efficiency and lifespan.

These and other aspects and characteristics of embodiments according to the present disclosure will become more apparent to those of ordinary skill in the art upon review of the Detailed Description and Claims to follow.

According to some embodiments of the present disclosure, a display device includes: a substrate; a first electrode located on the substrate; an emissive layer located on the first electrode; an electron transport layer located on the emissive layer; an electron injection layer located on the electron transport layer; and a second electrode located on the electron injection layer and containing silver (Ag), wherein the electron transport layer includes: a first electron transport layer; and a second electron transport layer located on a surface of the first electron transport layer, wherein a surface of the second electron transport layer is in contact with the electron injection layer, and a refractive index of the second electron transport layer is greater than a refractive index of the first electron transport layer, and wherein the second electrode includes: a first sub-electrode containing silver (Ag); and a second sub-electrode located on the first sub-electrode and containing ytterbium (Yb) and/or magnesium (Mg).

According to some embodiments, the electron transport layer further includes: a third electron transport layer arranged on an opposite surface of the first electron transport layer, and wherein a surface of the third electron transport layer is in contact with the emissive layer, and wherein a refractive index of the third electron transport layer is greater than the refractive index of the first electron transport layer.

According to some embodiments, a surface roughness of the second electron transport layer is smaller than a surface roughness of the first electron transport layer.

According to some embodiments, the surface roughness of the second electron transport layer is equal to or less than 1.0 nm RMS.

According to some embodiments, a thickness of the electron transport layer ranges from 5 nm to 50 nm.

According to some embodiments, the first electron transport layer and the second electron transport layer contain a same material.

According to some embodiments, a mass ratio between the first electron transport layer and the second electron transport layer is 3:1 to 50:1.

According to some embodiments, a capping layer located on the second electrode.

According to some embodiments of the present disclosure, in a method for fabricating a display device the method includes: forming a first electrode on a substrate; forming an emissive layer on the first electrode; forming an electron transport layer on the emissive layer; forming an electron injection layer on the electron transport layer; and forming a second electrode containing silver (Ag) on the electron injection layer, wherein the forming the electron transport layer includes: forming a first electron transport layer on the emissive layer; and forming a second electron transport layer on the first electron transport layer, wherein a deposition rate of the first electron transport layer is different from a deposition rate of the second electron transport layer, and wherein the forming the second electrode includes: forming a first sub-electrode containing silver (Ag) on the electron injection layer; and forming a second sub-electrode containing ytterbium (Yb) and/or magnesium (Mg) on the first sub-electrode.

According to some embodiments, the deposition rate of the first electron transport layer is slower than the deposition rate of the second electron transport layer.

According to some embodiments, a refractive index of the second electron transport layer is greater than a refractive index of the first electron transport layer.

According to some embodiments, the second electrode is formed by thermal deposition.

According to some embodiments, the forming the electron transport layer further includes: prior to the forming the first electron transport layer, forming a third electron transport layer on the emissive layer, wherein a refractive index of the third electron transport layer is greater than a refractive index of the first electron transport layer.

According to some embodiments, the electron transport layer is formed by thermal deposition.

According to some embodiments, the first electron transport layer, the second electron transport layer and the third electron transport layer contain a same material.

According to some embodiments, a surface roughness of the second electron transport layer is smaller than a surface roughness of the first electron transport layer.

According to some embodiments, a surface roughness of the second electron transport layer is equal to or less than 1.0 nm RMS.

According to some embodiments, a mass ratio between the first electron transport layer and the second electron transport layer is 3:1 to 50:1.

According to some embodiments, the method further includes: forming a capping layer on the second sub-electrode.

According to some embodiments of the present disclosure, an electronic device includes: a display device for displaying images, wherein the display device includes: a substrate; a first electrode located on the substrate; an emissive layer located on the first electrode; an electron transport layer located on the emissive layer; an electron injection layer located on the electron transport layer; and a second electrode located on the electron injection layer and containing silver (Ag), wherein the electron transport layer includes: a first electron transport layer; and a second electron transport layer located on a surface of the first electron transport layer, wherein a surface of the second electron transport layer is in contact with the electron injection layer, and a refractive index of the second electron transport layer is greater than a refractive index of the first electron transport layer, and wherein the second electrode includes: a first sub-electrode containing silver (Ag); and a second sub-electrode located on the first sub-electrode and containing ytterbium (Yb) and/or magnesium (Mg).

According to some embodiments of the present disclosure, a display device includes a first electron transport layer having a low refractive index, and thus surface plasmon polariton can be prevented from being excited and a resonance distance between a first electrode and a second electrode can be maintained. In addition, the efficiency and lifespan of the light-emitting element layer can be relatively improved.

Furthermore, by arranging a second electron transport layer having a high refractive index between the first electron transport layer and the second electrode, it is possible to improve the film quality of the second electrode.

The conductivity and film stability of the second electrode can be improved by using a first sub-electrode containing silver (Ag) and a second sub-electrode capable of preventing or reducing aggregation of silver (Ag).

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in more detail aspects of some embodiments thereof with reference to the attached drawings, in which:

FIG. 1 is a perspective view of a display device according to some embodiments of the present disclosure.

FIG. 2 is a side view of a display device according to some embodiments of the present disclosure.

FIG. 3 is a cross-sectional view showing the display panel according to some embodiments of the present disclosure.

FIG. 4 is an enlarged cross-sectional view of area A of FIG. 3, showing the structure of a light-emitting element according to some embodiments.

FIG. 5 is an enlarged cross-sectional view of area A of FIG. 3, showing the structure of a light-emitting element according to some embodiments.

FIG. 6 is a flowchart for illustrating a method of fabricating a display device according to some embodiments of the present disclosure.

FIG. 7 is a flowchart for illustrating a method for fabricating an electron transport layer according to some embodiments of the present disclosure.

FIG. 8 is an AFM (atomic force microscope) image showing the surface roughness of an electron transport layer when deposition is carried out at the deposition rate of 0.1 Å/s according to some embodiments.

FIG. 9 is an AFM (atomic force microscope) image showing the surface roughness of an electron transport layer when deposition is carried out at the deposition rate of 0.5 Å/s according to some embodiments.

FIG. 10 is an AFM (atomic force microscope) image showing the surface roughness of an electron transport layer when deposition is carried out at the deposition rate of 2.5 Å/s according to some embodiments.

FIG. 11 is a flowchart for illustrating a method for fabricating a second electrode according to some embodiments of the present disclosure.

FIG. 12 is a block diagram of an electronic device according to some embodiments of the present disclosure.

FIG. 13 is a view showing electronic devices according to some embodiments of the present disclosure.

### DETAILED DESCRIPTION

The characteristics and features of some embodiments of the present invention, and the methods for achieving them, will become clear with reference to the embodiments described below in more detail with the accompanying drawings. However, embodiments according to the present invention are not limited to the embodiments disclosed below, but may be implemented in various different forms, and these embodiments are provided only to make the disclosure of the present invention complete and to fully inform those skilled in the art of the invention of the scope of the invention, and the present invention is defined only by the scope of the claims.

When elements or layers are referred to as “on” another element or layer, this includes all cases where another layer or another element is interposed directly over or in the middle of the other element. The same reference numerals refer to the same components throughout the specification. The shapes, sizes, ratios, angles, numbers, etc. disclosed in the drawings for explaining the embodiments are examples, and therefore the present invention is not limited to the matters illustrated.

Although the terms “first” and “second” are used to describe various components, these components are not limited by these terms. These terms are only used to distinguish one component from another. Therefore, it goes without saying that the first component mentioned below may be the second component within the technical idea of the present invention.

Each of the features of the various embodiments of the present invention may be partially or wholly combined or combined with each other, and various technical connections and operations are possible, and each embodiment may be implemented independently of each other or may be implemented together in a related relationship.

Specific embodiments will be described below with reference to the attached drawings.

Hereinafter, aspects of some embodiments of the present disclosure will be described in detail with reference to the accompanying drawings.

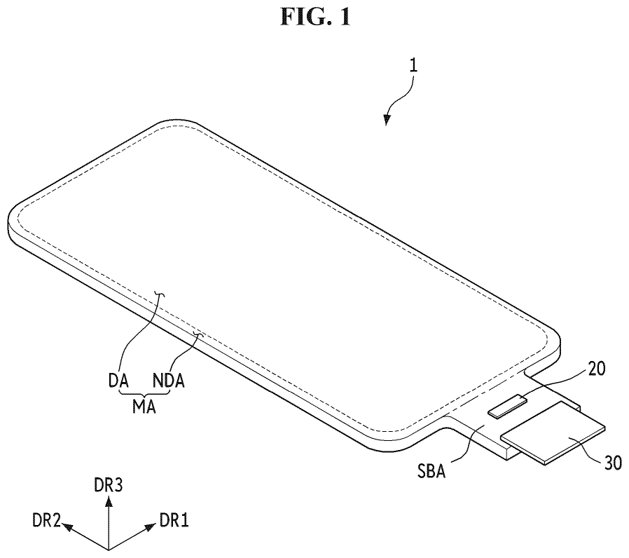

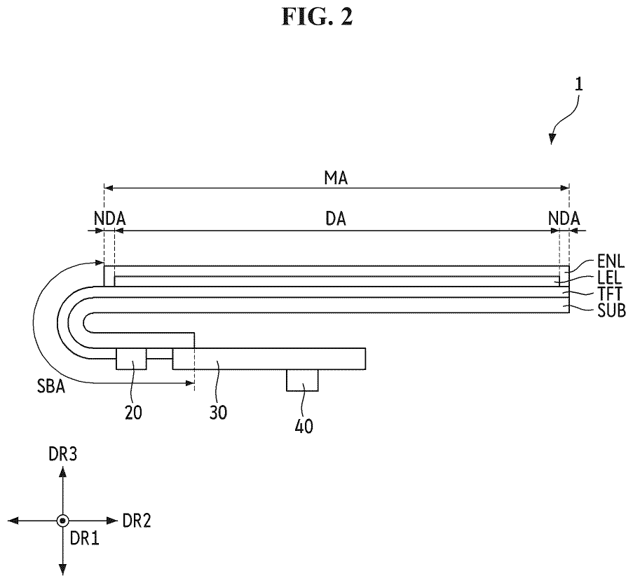

FIG. 1 is a plan view of a display device according to some embodiments of the present disclosure. FIG. 2 is a side view of a display device according to some embodiments of the present disclosure.

Referring to FIG. 1, a display device 1 according to some embodiments of the present disclosure is for displaying moving images (e.g., video images) or still images (e.g., static images). The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things (IoT) devices.

According to some embodiments of the present disclosure, the display device 1 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 1 according to some embodiments. It is, however, to be understood that embodiments of the present disclosure are not limited thereto.

The display device 100 includes a display panel 10, a display driver circuit 20, and a circuit board 30.

The display panel 1 may be formed in a rectangular plane having shorter sides in the first direction DR1 and longer sides in the second direction DR2 intersecting the first direction DR1. In addition, the display panel 100 may have a thickness in the third direction DR3 that intersects the first direction DR1 and the second direction DR2. Each of the corners where the shorter side in the first direction DR1 meets the longer side in the second direction DR2 may be rounded with a curvature (e.g., a set or predetermined curvature) or may be a right angle. The shape of the display panel 1 when viewed from the top (e.g., in a plan view) is not limited to a quadrangular shape, but may be formed in a different polygonal shape, an irregular shape, a circular shape, or an elliptical shape. The display panel 1 may be formed to be flat or planar, but embodiments according to the present disclosure are not limited thereto. For example, the display panel 1 may be formed at left and right ends, and may include a curved portion having a constant curvature or a varying curvature. In addition, the display panel 1 may be flexible so that it can be curved, bent, folded or rolled.

The display panel 1 may include the main area MA and a subsidiary area SBA.

The main area MA may include a display area DA where images are displayed, and a non-display area NDA around (e.g., surrounding, in a periphery, or outside a footprint of) the display area DA. The display area DA may occupy most of the main area MA. The display area DA may be located at the center of the main area MR. The non-display area NDA may be located adjacent to the display area DA. The non-display area NDA may be located on the outer side of the display area DA. The non-display area NDA may surround the display area DA. The non-display area NDA may be defined as the border of the display panel 100. A plurality of pixels PX for displaying images may be arranged in the display area DA. The display area DA may include pixels PX to display images. For example, the display area DA may include pixel areas where the pixels PX are arranged.

The subsidiary area SBA may be extending from one side of the main area MA in the first direction DR1. The length of the subsidiary area SBA in the first direction DR1 may be smaller than the length of the main area MA in the first direction DR1. The length of the subsidiary area SBA in the second direction DR2 may be less than the length of the main area MA in the second direction DR2 or may be substantially equal to it. The sub-area SBA may be bent and may be located under the display panel 100. In this instance, the subsidiary area SBA may overlap with the main area MA in the third direction DR3.

The display driver circuit 20 may generate signals and voltages for driving the display panel 1. The display driver circuit 20 may be implemented as an integrated circuit (IC) and may be attached to the subsidiary area SBA of the display panel 1 by a chip on glass (COG) technique, a chip on plastic (COP) technique, or an ultrasonic bonding. Alternatively, the display driver circuit 20 may be attached on the circuit board 30 by the chip-on-film (COF) technique.

The circuit board 30 may be attached to one end of the subsidiary area SBA of the display panel 1. Accordingly, the circuit board 30 may be electrically connected to the display panel 1 and the display driver circuit 20. The display panel 1 and the display driver circuit 20 may receive digital video data, timing signals, and driving voltages through the circuit board 30. The circuit board 30 may be a flexible printed circuit board, a printed circuit board, or a flexible film such as a chip on film.

A light-blocking layer for absorbing light incident from the outside, a buffer layer for absorbing impact from the outside, and a heat-dissipation layer for efficiently discharging heat from the display panel 100 may be further included under the display panel 100.

The light-blocking layer can block transmission of light, thereby preventing or reducing visibility of elements located under the light-blocking layer from above the display panel 100. The light-blocking layer may include a light-absorbing material such as a black pigment and a black dye.

The buffer layer can absorb external shock to prevent or reduce damage to the display panel 100. The buffer layer may be made up of a single layer or multiple layers. For example, the buffer layer may be formed of a polymer resin such as polyurethane, polycarbonate, polypropylene and polyethylene, or may be formed of a material having elasticity such as a rubber and a sponge obtained by foaming a urethane-based material or an acrylic-based material.

The heat sink layer may include a first heat dissipation layer including graphite or carbon nanotubes, and a second heat dissipation layer formed of a thin metal film such as copper, nickel, ferrite and silver, which can block electromagnetic waves and have high thermal conductivity.

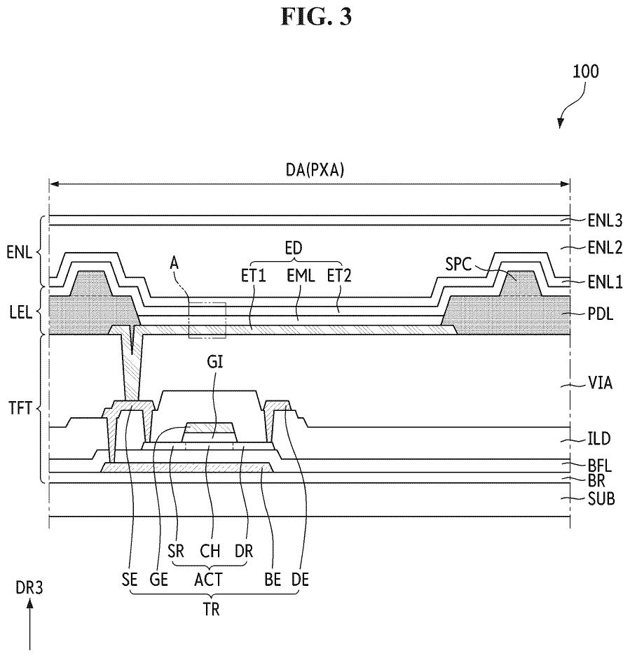

FIG. 3 is a cross-sectional view showing the display panel according to some embodiments of the present disclosure. For example, FIG. 3 shows a portion of the display area DA of the display panel 100. FIG. 3 shows a light-emitting display panel including a light-emitting element ED (e.g., an organic light-emitting diode) as an example of the display panel 100 according to the embodiments of the present disclosure.

Referring to FIG. 3, the display panel 100 may include a substrate SUB (or a base layer), a thin-film transistor layer TFT, a light-emitting element layer LEL, and an encapsulation layer ENL. The thin-film transistor layer TFT, the light-emitting element layer LEL and the encapsulation layer ENL may be located on the substrate SUB such that they overlap one another. For example, in the display area DA, the thin-film transistor layer TFT, the light-emitting element layer LEL and the encapsulation layer ENL may be sequentially arranged on the substrate SUB in the third direction D3.

According to some embodiments of the present disclosure, the display panel 100 may further include additional elements located on and/or under the encapsulation layer ENL. For example, the display panel 100 may further include at least one of a sensor layer (e.g., a touch sensor layer), an optical layer (e.g., a color filter layer and/or a wavelength conversion layer), or a protective layer (e.g., a protective film, an insulating layer, an upper substrate and/or a window). Each of the sensor layer, optical layer and/or protective layer may be arranged over the encapsulation layer ENL or between the light-emitting element layer LEL and the encapsulation layer ENL.

The substrate SUB may be a base member for forming the display panel 100 and may be rigid or flexible. According to some embodiments of the present disclosure, the substrate SUB may be a substrate that includes an insulating material such as glass and is rigid, which may not be bendable. Alternatively, the substrate SUB may be a flexible substrate that includes polyimide or other insulating material and allows deformation such as bending, folding or rolling, and may be bent or not bent.

The thin-film transistor layer TFT (e.g., a backplane circuit layer or a thin-film transistor layer) may be arranged on the substrate SUB. The thin-film transistor layer TFT may include circuit elements including pixel transistors PXT and capacitors C of the pixels PX, and lines (e.g., signal lines and voltage lines).

According to some embodiments of the present disclosure, the transistors TR may be formed simultaneously using the same material and may have substantially the same or similar cross-sectional structures. For example, the transistors TR of the pixels PX may be formed simultaneously using the same oxide semiconductor and may have substantially the same or similar cross-sectional structures. For example, the active layers ACT of the transistors TR may be arranged in the same layer (e.g., on the buffer layer BFL) in the thin-film transistor layer TFT and may include the same oxide semiconductor.

The thin-film transistor layer TFT may include a plurality of conductive layers and at least one semiconductor layer arranged on the substrate SUB (or a barrier layer BR). In addition, the thin-film transistor layer TFT may further include a plurality of insulating layers and/or insulating patterns arranged on the substrate SUB (or the barrier layer BR).

Patterns included in the conductive layers of the thin-film transistor layer TFT may include electrodes forming circuit elements of the thin-film transistor layer TFT, conductive patterns connected to the circuit elements, and/or lines, etc. Patterns included in each conductive layer of the thin-film transistor layer TFT (e.g., electrodes, conductive patterns and/or lines of each conductive layer) may include at least one conductive material. For example, patterns included in each conductive layer of the thin-film transistor TFT layer may include at least one of copper (Cu), titanium (Ti), molybdenum (Mo), aluminum (AI), chromium (Cr), gold (Au), silver (Ag), platinum (Pt), palladium (Pd), nickel (Ni), neodymium (Nd), iridium (Ir), tantalum (Ta), tungsten (W), magnesium (Mg) or other metals, an alloy thereof, or other conductive material. According to some embodiments of the present disclosure, the patterns included in the same conductive layer may be formed simultaneously using the same conductive material.

Patterns included in the semiconductor layer of the thin-film transistor layer TFT may include active layers ACT of transistors arranged in the thin-film transistor layer TFT. According to some embodiments of the present disclosure, the active layers ACT of the pixel transistors PXT and circuit transistors may be formed together using the same semiconductor material (e.g., the same oxide semiconductor). Accordingly, the active layers ACT of the transistors TR and the circuit transistors may be arranged in the same layer and may include the same semiconductor material.

The insulating layers and/or insulating patterns of the thin-film transistor layer TFT may include a barrier layer BR, a buffer layer BFL, a gate insulator GI, an interlayer dielectric layer ILD and a planarization layer VIA sequentially arranged on the substrate SUB along the third direction D3. Each of the insulating layers and/or insulating patterns of the thin-film transistor layer TFT may include an inorganic insulating material or an organic insulating material, and may be made up of a single layer or multiple layers.

According to some embodiments of the present disclosure, at least one of the insulating layers of the thin-film transistor layer TFT may be located over the entire display area DA. For example, the barrier layer BR, the buffer layer BFL, the interlayer dielectric layer ILD and the planarization layer VIA may be located over the entire display area DA.

Each layer of the structure of the thin-film transistor layer TFT will be described. First, the barrier layer BR may be placed on the substrate SUB. The barrier layer BR may include at least one inorganic insulating layer including an inorganic insulating material (e.g., silicon nitride (SiNx), silicon oxide (SiOx), silicon oxynitride (SiON), titanium oxide (TiOx), aluminum oxide (AlxOy), or other inorganic insulating materials). The barrier layer BR can protect the pixels PX from moisture permeating through the substrate SUB, which is vulnerable to moisture permeation. The barrier layer BR may be eliminated.

A first conductive layer (e.g., a lower conductive layer) including a bottom electrode BE (or a light-blocking layer) of at least one transistor may be arranged on the barrier layer BR (or substrate SUB). For example, the bottom electrode BE (or the light-blocking layer) of the transistor TR may be placed on the barrier layer BR. The bottom electrode BE may be arranged under the active layer ACT such that it overlaps with the channel region CH of the transistor TR. According to some embodiments of the present disclosure, the bottom electrode BE may also overlap with at least parts of the source region SR and the drain region DR of the transistor TR, but embodiments according to the present disclosure are not limited thereto. Each of the patterns of the first conductive layer including the bottom electrode BE may include at least one conductive material and may be made up of a single layer or multiple layers.

According to some embodiments of the present disclosure, the bottom electrode BE may be electrically connected to one electrode of the transistor TR (e.g., the source electrode SE) and may be used as an electrode to adjust the characteristics of the transistor TR. For example, the bottom electrode BE may be electrically connected to the source electrode SE of the transistor TR. When the bottom electrode BE is electrically connected to one electrode of the transistor TR, the bottom electrode BE may also be regarded as an element included in the transistor TR. By disposing the bottom electrode BE under the active layer ACT, it is possible to block external light from entering the channel region CH of the transistor TR. According to some embodiments of the present disclosure where the transistors of the thin-film transistor layer TFT do not include the bottom electrode BE or the light-blocking layer, the first conductive layer may be eliminated.

The buffer layer BFL may be located on the barrier layer BR and the bottom electrode BE. The buffer layer BFL may include at least one inorganic insulating layer including an inorganic insulating material (e.g., silicon nitride (SiNx), silicon oxide (SiOx), silicon oxynitride (SiON), titanium oxide (TiOx), aluminum oxide (AlxOy), or other inorganic insulating materials).

The buffer layer BF may include an insulating material suitable as a barrier material that can prevent or reduce diffusion of oxygen, hydrogen, etc. The buffer layer BFL may include other insulating materials capable of appropriately blocking oxygen, hydrogen and/or moisture, in addition to a silicon nitride film containing silicon nitride (SiNx) and a silicon oxide film containing silicon oxide (SiOx).

The active layer ACT may include the channel region CH, the source region SR and the drain region DR. The channel region CH may overlap with the gate electrode GE in the third direction DR3 when viewed from the top (e.g., in a plan view), and may be located between the source region SR and the drain region DR. The source region SR and the drain region DR may be located on the opposite sides of the channel region CH, respectively, and may be spaced apart from each other with the channel region CH therebetween. The source region SR and the drain region DR (or a part of each of the source region SR and the drain region DR) may not overlap with the gate electrode GE when viewed from the top (e.g., in a plan view). The carrier concentration (e.g., electron concentration) of the source region SR and the drain region DR may be higher than the carrier concentration of the channel region CH.

According to some embodiments of the present disclosure, the active layers ACT may include oxide semiconductor. For example, the active layers ACT may include an oxide semiconductor including at least one of indium (In), gallium (Ga), zinc (Zn), tin (Sn) and hafnium (Hf), or other oxide semiconductor. According to some embodiments of the present disclosure, the active layers ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), or other oxide semiconductors.

According to some embodiments, the active layers ACT of some of the transistors arranged in the thin-film transistor layer TFT may be located on the buffer layer BFL.

According to some embodiments of the present disclosure, at least one transistor TR may be arranged in each pixel area PXA. Accordingly, a plurality of transistors TR may be arranged in the display area DA.

The gate insulator GI may be located on the active layer ACT. For example, the gate insulator GI may be located on a portion of each of the active layers ACT including the respective channel regions CH.

The gate insulator GI may include at least one inorganic insulating layer including an inorganic insulating material (e.g., silicon nitride (SiNx), silicon oxide (SiOx), silicon oxynitride (SiON), titanium oxide (TiOx), aluminum oxide (AlxOy), or other inorganic insulating materials).

According to some embodiments of the present disclosure, the gate insulator GI may have an etched shape to cover a portion of the active layer ACT and the other portion of the active layer ACT in each transistor region in which the respective transistor is placed. For example, in a region where a transistor TR is placed, the gate insulator GI may cover the channel region CH of the active layer ACT included in the transistor TR and may expose the source region SR and the drain region DR of the active layer ACT.

As the gate insulator GI exposes the source regions SR and drain regions DR, the conductivity of the source regions SR and drain regions DR can be increased properly and/or easily during the process of fabricating the display panel 100. For example, in a process of etching the gate insulator GI so that at least a part of each of the source regions SR and the drain regions DR is exposed, the carrier concentrations of the source regions SR and the drain regions DR may be increased in a subsequent process (e.g., a process of forming an interlayer dielectric layer ILD) due to oxygen vacancies occurring in the source regions SR and the drain regions DR without performing a separate doping process.

It should be understood, however, that the embodiments of the present disclosure are not limited thereto. For example, the gate insulator GI may entirely cover the active layers ACT of some or all of the transistors included in the thin-film transistor layer TFT, except for a contact hole for connecting each of the transistors with other circuit elements or lines.

A second conductive layer (e.g., a gate conductive layer) including gate electrodes GE may be located on the gate insulator GI. For example, the gate electrode GE of the transistor TR may be located on the gate insulator GI covering the channel region CH of the transistor TR. Each of the patterns of the second conductive layer including the gate electrodes GE may include at least one conductive material and may be made up of a single layer or multiple layers.

The interlayer dielectric layer ILD may be located on the buffer layer BFL, the semiconductor layer including the active layers ACT, the gate insulator GI and the second conductive layer including gate electrodes GE. For example, the interlayer dielectric layer ILD may be placed on the buffer layer BFL to cover the semiconductor layer, the gate insulator GI and the patterns of the second conductive layer. The interlayer dielectric layer ILD may include at least one inorganic insulating layer containing an inorganic insulating material.

A third conductive layer (e.g., a source-drain conductive layer) including the source electrodes SE, the drain electrodes DE, and/or conductive patterns electrically connected to at least some of the transistors TR may be located on the interlayer dielectric layer ILD. For example, the third conductive layer may include the source electrode SE and the drain electrode DE of the transistor TR. Each of the patterns of the third conductive layer may include at least one conductive material and may be made up of a single layer or multiple layers.

The source electrode SE and the drain electrode DE of the transistor TR may be electrically connected to the source region SR and the drain region DR of the transistor TR, respectively, through the interlayer dielectric layer ILD. According to some embodiments of the present disclosure, the source electrode SE of the transistor TR may also be electrically connected to the bottom electrode BE of the transistor TR through the interlayer dielectric layer ILD and the buffer layer BFL.

The planarization layer VIA may be located over the transistor TR. For example, the planarization layer VIA may be located on the interlayer dielectric layer ILD and the third conductive layer. The planarization layer VIA may include at least one organic insulating layer containing an organic insulating material (e.g., an acrylic resin, an epoxy resin, a phenolic resin, a polyamide resin, a polyimide resin, or other organic insulating materials). The planarization layer VIA may or may not include an inorganic insulating layer. A surface (e.g., upper surface) of the planarization layer VIA may be substantially flat.

The light-emitting element layer LEL may be located on the thin-film transistor layer TFT. For example, the light-emitting element layer LEL may be located on the planarization layer VIA and may be located at least in the display area DA.

The light-emitting element layer LEL may include a light-emitting element ED of each of the pixels PX. For example, the light-emitting element layer LEL may include a pixel-defining layer PDL (also referred to as a “bank”) that partitions the emission area of each of the pixels PX, and a light-emitting element ED located in each emission area. According to some embodiments of the present disclosure, the light-emitting element layer LEL may further include a spacer SPC located on a portion of the pixel-defining layer PDL.

Each of the light-emitting elements EL may include a first electrode ET1 located in each emission area, and an emissive layer EML and a second electrode ET2 sequentially located on the first electrode ET1. The first electrode ET1 of the light-emitting element ED may be electrically connected to at least one transistor TR included in that pixel PX through the planarization layer VIA.

The first electrode ET1 of the light-emitting element ED may be a single-layer or multi-layer electrode containing at least one conductive material. According to some embodiments of the present disclosure, the display panel 100 may be a top-emission display panel. The first electrode ET1 may include a reflective electrode layer containing at least one material among aluminum (AI), molybdenum (Mo), titanium (Ti), copper (Cu), silver (Ag), magnesium (Mg), platinum (Pt), palladium (Pd), gold (Au), nickel (Ni), neodymium (Nd), iridium (Ir) and chromium (Cr), or other reflective conductive material.

The emissive layer EML of each of the light-emitting elements ED may include a high-molecular substance or a low-molecular substance. Light emitted from the emissive layer EML may contribute to displaying images.

Although FIG. 3 shows the display panel 100 in which the emissive layer EML of the light-emitting element ED is individually formed in the respective pixel area PXA, the embodiments of the present disclosure are not limited thereto. For example, the display panel 100 may include light-emitting elements in a tandem structure including the emissive layer EML formed as a common film over the entire display area DA.

The second electrode ET2 of the light-emitting element ED may include a conductive material. According to some embodiments of the present disclosure, the second electrode ET2 may be a common layer formed over the entire display area DA to cover the emissive layer EML and the pixel-defining layer PDL. According to some embodiments of the present disclosure, the display panel 100 may be a top-emission display panel, and the second electrode ET2 may include a transparent or translucent electrode layer.

The second electrode ET2 may use silver (Ag) that can transmit light in a top-emission structure. While silver (Ag) has high transmittance and low resistance, it is prone to agglomeration due to its high surface energy, which may deteriorate the stability of a thin film. To prevent or reduce this, silver (Ag) may be mainly used as a semi-transmissive conductive material doped with magnesium (Mg) or made into an alloy. However, when magnesium (Mg) is mixed with silver (Ag), the resistance may increase and the light absorption may increase, which may deteriorate the resistance and light efficiency.

When the second electrode ET2 is made of a semi-transmissive conductive material, the light extraction efficiency of each of the light-emitting elements ED can be increased by micro-cavity.

According to some embodiments of the present disclosure, the stability and efficiency of a thin film can be improved by using silver (Ag) as the second electrode ET2. A more detailed description thereon will be given later.

The pixel-defining layer PDL may have openings associated with the respective emission areas and may surround the emission areas. For example, the pixel-defining layer PDL may be formed to cover an edge of the first electrode ET1 of the light-emitting element ED, and may include an opening that exposes the remaining portion of the first electrode ET1. The area where the exposed portion of the first electrode ET1 and the emissive layer EML overlap each other may be the emission area of each pixel PX. According to some embodiments of the present disclosure, the pixel-defining layer PDL may be made of an organic material. The pixel-defining layer may include a light-blocking material. The pixel-defining layer PDL includes a base resin and a colorant. The base resin may include at least one of: a cardo resin, an epoxy resin, an acrylate resin, a siloxane resin, or polyimide. The colorant may be selected from a carbon pigment, a metal oxide pigment, and an organic pigment. For example, the carbon pigment may be selected from, but is not limited to, carbon black, carbon nanotubes, titanium black, vertically aligned nanotube arrays (VANTA) black, etc. For example, the metal oxide pigment may be, but is not limited to, titanium black (TiNxOy), Cu—Mn—Fe black pigment. For example, the organic pigment may be, but is not limited to, lactam black, perylene black, and aniline black. For another example, the colorant may be a mixture of two or more types of pigments or dyes having different colors. It should be understood, however, that the embodiments of the present disclosure are not limited thereto.

The spacer SPC may be located on a part of the pixel-defining layer PDL. The spacer SPC may include at least one organic insulating layer containing an organic insulating material. The spacer SPC may include the same material as the pixel-defining layer PDL or may include a different material from the pixel-defining layer PDL. The pixel-defining layer PDL and the spacer SPC may be formed sequentially via the respective mask processes, or may be formed simultaneously and/or integrally using a halftone mask.

The encapsulation layer ENL may be located on the light-emitting element layer LEL. The encapsulation layer ENL may cover the light-emitting element layer LEL in the display area DA and may be extending to the non-display area NDA to be in contact with the thin-film transistor layer TFT. The encapsulation layer ENL can block the permeation of oxygen or moisture into the light-emitting element layer LEL and can alleviate electrical and/or physical shock on the thin-film transistor layer TFT and the light-emitting element layer LEL.

According to some embodiments of the present disclosure, the encapsulation layer ENL may include a first encapsulation layer ENL1, a second encapsulation layer ENL2, and a third encapsulation layer ENL3 sequentially located on the emission material layer LEL. Each of the first encapsulation layer ENL1 and the third encapsulation layer ENL3 may be an inorganic encapsulation layer containing an inorganic material. The second encapsulation layer ENL2 may be an organic encapsulation layer containing an organic material.

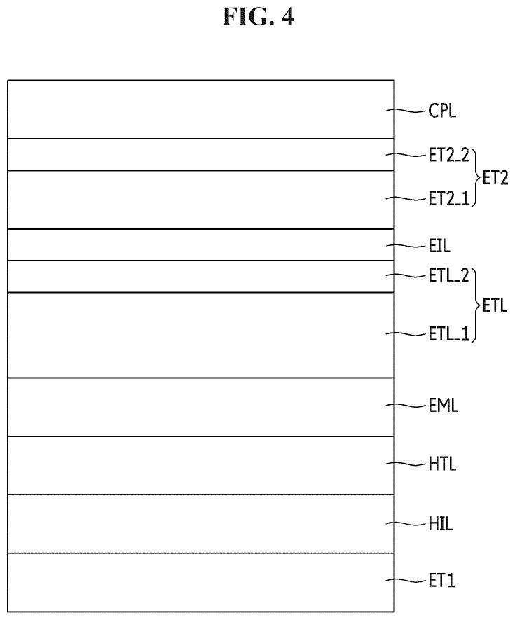

FIG. 4 is an enlarged cross-sectional view of area A of FIG. 3, showing the structure of a light-emitting element according to some embodiments.

Referring to FIG. 4, the light-emitting element layer LEL may include a first electrode ET1, a hole injection layer HIL, a hole transport layer HTL, an emission layer EML, an electron transport layer ETL, an electron injection layer EIL, a second electrode ET2, and a capping layer CPL.

In the light-emitting element layer LEL, the hole injection layer HIL may be located on the first electrode ET1, and the hole transport layer HTL may be located on the hole injection layer HIL. The hole injection layer HIL may be located directly on the first electrode ET1. The hole injection layer HIL may facilitate injection of holes into the emissive layer EML. According to some embodiments, the hole injection layer HIL may be made of, but is not limited to, at least one selected from the group consisting of: CuPc (copper phthalocyanine), PEDOT (poly(3,4)-ethylenedioxythiophene), PANI (polyaniline) and NPD (N,N-dinaphthyl-N,N′-diphenyl benzidine).

The hole transport layer HTL may be located on the hole injection layer HIL. The hole transport layer HTL may facilitate the transport of holes and may include a hole transport material. The hole transport material may include, but is not limited to, carbazole derivatives such as N-phenylcarbazole and polyvinylcarbazole, fluorene derivatives, triphenylamine derivatives such as TPD(N,N′-bis(3-methylphenyl)-N,N′-diphenyl-[1,1-biphenyl]-4,4′-diamine) and TCTA (4,4′,4″-tris(N-carbazolyl)triphenylamine), NPB(N,N′-di(1-naphthyl)-N,N′-diphenylbenzidine), TAPC(4,4′-Cyclohexylidene bis[N,N-bis(4-methylphenyl)benzenamine]), etc.

In the light-emitting element layer LEL, a functional layer may be located on the first electrode ET1. The functional layer may include the hole injection layer HIL and the hole transport layer HTL.

The emissive layer EML may be located on the first electrode ET1, the hole transport layer HTL, or the functional layer. The emissive layer EML may emit the lights of different colors in different emission areas. For example, the emissive layer EML of the first emission area may emit light of a first color, for example, blue light. The emissive layer EML of the second emission area may emit light of a second color, for example, red light. The emissive layer EML of the third emission area may emit light of a third color, for example, green light.

The electron transport layer ETL may be arranged on the emissive layer EML.

The electron transport layer ETL may include electron transparent material such as Alq3(Tris(8-hydroxyquinolinato)aluminum), TPBi(1,3,5-Tri(1-phenyl-1H-benzo[d]imidazol-2-yl)phenyl), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate), ADN(9,10-di(naphthalene-2-yl)anthracene) and a mixture thereof. It is to be noted that the type of the electron transport material is not particularly limited herein.

The electron transport layer ETL may include a first electron transport layer ETL_1 located on the emissive layer EML, and a second electron transport layer ETL_2 located on the first electron transport layer ETL_1.

The refractive index of the second electron transport layer ETL_2 may be greater than the refractive index of the first electron transport layer ETL_1.

The electron injection layer EIL may be located on the second electron transport layer ETL_2, and the second electron transport layer ETL_2 may be in contact with the electron injection layer EIL.

The electron injection layer EIL may include, but is not limited to, at least one of ytterbium (Yb), samarium (Sm), europium (Eu), magnesium (Mg), lithium (Li), sodium (Na), potassium (K), rubidium (Rb), cesium (Cs), or francium (Fr).

The electron injection layer EIL may work as a lower electrode of the second electrode ET2.

The thickness of the electron injection layer ETIL may be, but is not limited to, 5 Å to 30 Å.

A first sub-electrode ET2_1 containing silver (Ag) may be located on the electron injection layer EIL. The first sub-electrode ET2_1 may be made of undoped pure silver (Ag) as an electrode to improve conductivity and light efficiency.

A second sub-electrode ET2_2 containing ytterbium (Yb) and/or magnesium (Mg) may be located on the first sub-electrode ET2_1.

The second sub-electrode ET2_2 may include ytterbium (Yb) or may include ytterbium (Yb) and magnesium (Mg). When the second sub-electrode ET2_2 is formed by co-depositing ytterbium (Yb) and magnesium (Mg), the mass ratio between ytterbium (Yb) and magnesium (Mg) may be 1:1 to 5:1.

A capping layer CPL may be located on the second sub-electrode ET2_2. The capping layer CPL may include an inorganic insulating material or an organic material. The capping layer CPL may cover the light-emitting element layer LEL, and patterns located on the pixel-defining layer PDL and the spacer SPC. The capping layer CPL can prevent or reduce damage to the light-emitting element layer LEL due to the external air, and can prevent or reduce instances of the patterns arranged on the pixel-defining layer PDL and the spacer SPC falling off during the process of fabricating the display device 1.

The thickness of the second electrode ET2 may be, but is not limited to, 50 Å to 300 Å.

The binding energy between the material included in the capping layer CPL and the silver (Ag) of the first sub-electrode ET2_1 may be low. Accordingly, if the capping layer CPL is placed directly on the first sub-electrode ET2_1 containing silver (Ag) without the second sub-electrode ET2_2, the silver (Ag) may diffuse into the capping layer CPL. By placing a metal having a high binding energy with silver (Ag) as the second sub-electrode ET2_2, it may be possible to effectively prevent or reduce instances of the silver (Ag) of the first sub-electrode ET2_1 diffusing into the capping layer CPL. In addition, ytterbium (Yb) and/or magnesium (Mg) contained in the second sub-electrode ET2_2 can effectively prevent or reduce agglomeration of silver (Ag).

Holes injected from the first electrode ET1 and electrons injected from the second electrode ET2 form excitons at a particular location in the emissive layer EML, and light can be emitted from the emissive layer EML by these excitons.

A micro-cavity may be sandwiched between the first electrode ET1 containing a reflective material and the second electrode ET2 containing a semi-transparent material. In order to facilitate micro-cavity, it may be necessary to adjust the resonance distance depending on the wavelength of light emitted from the emissive layer EML.

The conditions for micro-cavity may be obtained as follows. As the light wave must form nodes on the surface of the first electrode ET1 and the second electrode ET2 to generate a standing wave, the conditions for generating nodes are as shown in Equation 1 below:

$$nd cos θ = m \frac{λ}{2} \qquad Equation 1$$

where n denotes the refractive index of a layer, d denotes the thickness of the layer, θ denotes the incidence angle, and m denotes a natural number.

The penetration depth or skin depth of light may vary depending on the metal. The penetration depth of light may be calculated using Equation 2 below:

$$δ = \sqrt{\frac{ρ}{π {F}_{0} {μ}_{r} , {μ}_{0}}} \qquad Equation 2$$

where δ denotes the penetration depth, ρ denotes the resistivity of a conductor, f₀ denotes the frequency of light, μᵣ denotes the relative permeability, and μ₀ denotes the permeability in vacuum.

Compared to the second electrode ET2 containing silver (Ag) and magnesium (Mg), the penetration depth of light into the second electrode ET2 containing silver (Ag) having high resistivity may be increased.

By using the first sub-electrode ET2_1 containing silver (Ag), the penetration depth of light may be increased. Because the resonance distance of the light-emitting element layer LEL must be maintained, the thickness of the electron transport layer ETL may need to be reduced as the penetration depth of light increases. However, if the thickness of the electron transport layer ETL is reduced, externally incident light interacts between the first electrode ET1 and the second electrode ET2 to cause interference. As a result, surface plasmon polariton may be excited to absorb external light. In order to prevent or reduce instances of the light-emitting element layer LEL absorbing external light and thus the efficiency and lifespan may be relatively deteriorated, the refractive index of the electron transport layer ETL may be reduced by referring to Equation 1, instead of reducing the thickness of the electron transport layer ETL.

To sum up, when the first sub-electrode ET2_1 is made of silver (Ag) having high resistivity, the depth of light penetrating into the second electrode ET2 may increase. As the penetration depth of light increases, the resonance distance between the first electrode ET1 and the second electrode ET2 may change. In order to maintain the resonance distance, the thickness or refractive index of the electron transport layer may be adjusted. However, if the thickness of the electron transport layer is reduced, surface plasmon polariton may be excited, thereby increasing light absorption. According to some embodiments of the present disclosure, it may be possible to prevent or reduce surface plasmon polariton from being excited and maintain the resonance distance between the first electrode ET1 and the second electrode ET2 by reducing the refractive index of the electron transport layer ETL. In addition, the efficiency and lifespan of the light-emitting element layer LEL can be improved.

The surface of the first electron transport layer ETL_1 having a low refractive index is rough, and thus the film quality of a film formed on the first electron transport layer ETL_1 may deteriorate. According to some embodiments of the present disclosure, the film quality of the electron injection layer EIL and the second electrode ET2 can be improved by arranging the second electron transport layer ETL_2 having a high refractive index on the first electron transport layer ETL_1. As the film quality of the second electrode ET2 is improved, the thin film stability of the second electrode ET2 can be improved, so that the lifespan of the light-emitting element layer LEL can be improved.

The surface roughness of the second electron transport layer ETL_2 may be smaller than that of the first electron transport layer ETL_1. The surface roughness of the second electron transport layer ETL_2 may be equal to or less than 1.0 nm RMS. According to some embodiments, the surface roughness of the second electron transport layer ETL_2 may be equal to or less than 0.5 nm RMS. The surface roughness may be a value obtained by an atomic force microscope (AFM). The surface roughness is obtained based on vertical deviations of a roughness profile from an AFM cross-sectional image, and may be a root mean square (RMS) value of the roughness profile. Because the surface roughness of the second electron transport layer ETL_2 is small, the film quality of the electron injection layer EIL and the second electrode ET2 formed on the second electron transport layer ETL_2 can be improved.

The mass ratio between the first electron transport layer ETL_1 and the second electron transport layer ETL_2 may be from 3:1 to 50:1. The mass and thickness of the first electron transport layer ETL_1 may be adjusted depending on the refractive layer that the electron transport layer ETL is to reach.

The refractive index of the electron transport layer ETL may range from 1.0 to 2.0. The refractive index of the electron transport layer ETL may be adjusted depending on the node conditions. According to some embodiments, the refractive index of the electron transport layer ETL may range from 1.4 to 1.8. According to some embodiments, the refractive index of the electron transport layer ETL may range from 1.5 to 1.7.

The refractive index of the electron transport layer ETL may be adjusted depending mainly on the refractive index of the first electron transport layer ETL_1. The first electron transport layer ETL_1 may be a low-refractive material for lowering the refractive index of the electron transport layer ETL, and the second electron transport layer ETL_1 may be a high-refractive material for improving the film quality of the electron transport layer ETL.

The thickness of the electron transport layer may be, but is not limited to, 5 nm to 50 nm.

The electron transport layer ETL may include, for example, the first electron transport layer ETL_1 having a refractive index of 1.0 to 1.5, 250 Å, and the second electron transport layer ETL_2 having a refractive index of 1.5 to 2.0.

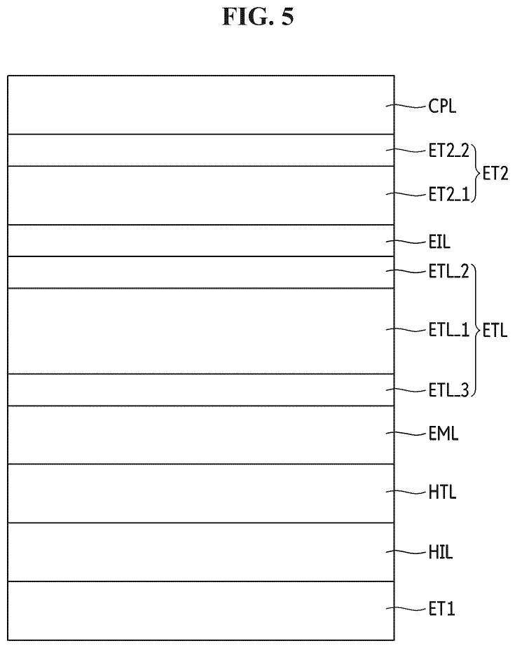

FIG. 5 is an enlarged cross-sectional view of area A of FIG. 3, showing the structure of a light-emitting element according to some embodiments.

The light-emitting element layer LEL of FIG. 5 is substantially identical to the light-emitting element layer LEL of the embodiments shown in FIG. 4 except that a third electron transport layer ETL_3 is added; and, therefore, the redundant descriptions will be omitted.

Referring to FIG. 5, a third electron transport layer ETL_3 may be further located under the first electron transport layer ETL_1. The refractive index of the third electron transport layer ETL_3 may be greater than the refractive index of the first electron transport layer ETL_1.

The surface roughness of the third electron transport layer ETL_3 may be smaller than that of the first electron transport layer ETL_1. The third electron transport layer ETL_3 may be a high-refractive material for improving the film quality of the emissive layer EML.

The first electron transport layer ETL_1, the second electron transport layer ETL_2 and the third electron transport layer ETL_3 may include the same material. The first electron transport layer ETL_1, the second electron transport layer ETL_2 and the third electron transport layer ETL_3 may be made of the same material but may have different refractive indexes by controlling the deposition rate. A detailed description thereon will be given later in describing a method for fabricating a display device.

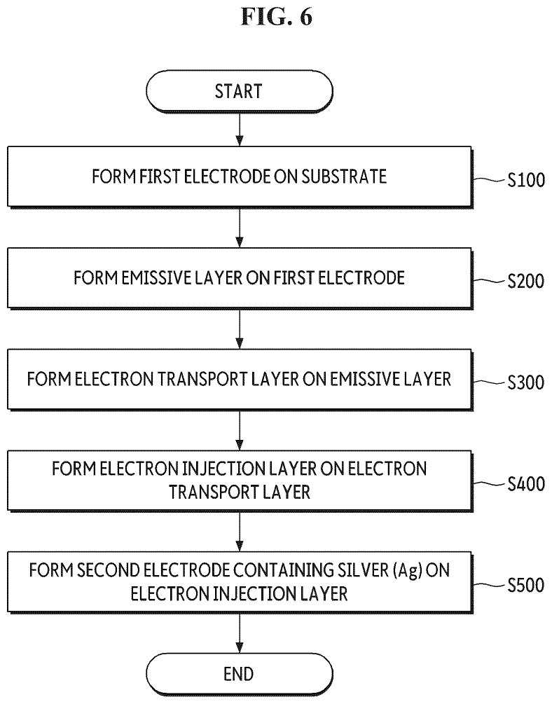

FIG. 6 is a flowchart for illustrating aspects of a method of fabricating a display device according to some embodiments of the present disclosure. Although FIG. 6 illustrates various operations in a method of fabricating a display device, according to some embodiments, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

Initially, a first electrode ET1 may be formed on a substrate SUB (step S100). The first electrode ET1 may be formed using the above-listed materials. A process for forming the first electrode ET1 is not particularly limited herein.

Subsequently, the method may further include forming a pixel-defining layer PDL on the substrate SUB including the first electrode ET1. By forming the pixel-defining layer PDL, each emission area may be defined. The pixel-defining layer PDL may be formed using the above-listed materials. A process for forming the pixel-defining layer PDL is not particularly limited herein.

Subsequently, the method may further include forming a spacer SPC on the pixel-defining layer PDL. The spacer SPC may be formed using the above-listed materials. A process for forming the spacer SPC is not particularly limited herein.

When the pixel-defining layer PDL and the spacer SPC are made of the same material, the pixel-defining layer PDL and the spacer SPC may be formed together.

Subsequently, a hole injection layer HIL may be formed on the first electrode ET1 in each emission area surrounded by the pixel-defining layer PDL. The hole injection layer HIL may be formed using the above-listed materials. A process for forming the hole injection layer HIL is not particularly limited herein.

Subsequently, a hole transport layer HTL may be formed on the hole injection layer HIL. The hole transport layer HTL may be formed using the above-listed materials. A process for forming the hole transport layer HTL is not particularly limited herein.

Subsequently, an emissive layer EML may be formed on the hole transport layer HTL or the first electrode ET1 (step S200). The emissive layer EML may be formed using the above-listed materials. A process for forming the emissive layer EML is not particularly limited herein.

Subsequently, an electron transport layer ETL may be formed on the emissive layer EML (step S300).

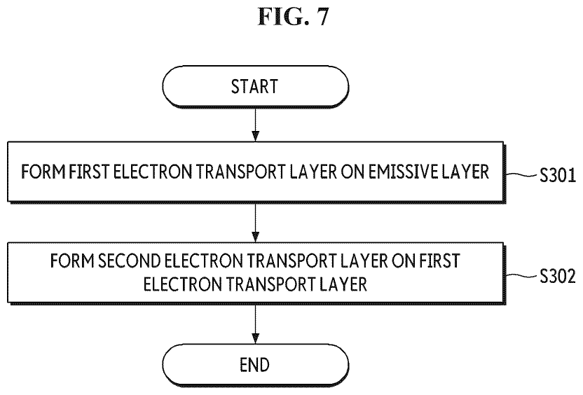

FIG. 7 is a flowchart for illustrating a method for fabricating an electron transport layer according to some embodiments of the present disclosure. Although FIG. 7 illustrates various operations in a method of fabricating an electron transport layer, according to some embodiments, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

First, a first electron transport layer ETL_1 may be formed on the emissive layer EML (step S301). The first electron transport layer ETL_1 may be formed using the above-listed materials. The first electron transport layer ETL_1 may be formed by thermal deposition. If plasma deposition is used, damage may occur on an organic thin film (such as the emissive layer). By using thermal deposition, it is possible to form an ultra-thin film without damaging an organic thin film.

Subsequently, a second electron transport layer ETL_2 may be formed on the first electron transport layer ETL_1 (step S302). The second electron transport layer ETL_2 may be formed using the above-listed materials. The second electron transport layer ETL_2 may be formed by thermal deposition.

The deposition rate of the first electron transport layer ETL_1 may be different from the deposition rate of the second electron transport layer ETL_2.

The first electron transport layer ETL_1 and the second electron transport layer ETL_2 may be made of the same material. The refractive index of each of the first electron transport layer ETL_1 and the second electron transport layer ETL_2 may increase as the density increases by increasing the deposition rate. The deposition rate of the first electron transport layer ETL_1 may be slower than the deposition rate of the second electron transport layer ETL_2.

Because the deposition rate of the first electron transport layer ETL_1 is slower than the deposition rate of the second electron transport layer ETL_2, the refractive index of the first electron transport layer ETL_1 may be smaller than the refractive index of the second electron transport layer ETL_2.

The forming the electron transport layer ETL may further include: forming the third electron transport layer ETL_3 on the emissive layer EML prior to the forming the first electron transport layer ETL_1. The third electron transport layer ETL_3 may be formed using the above-listed materials. The third electron transport layer ETL_3 may be formed by thermal deposition.

The deposition rate of the third electron transport layer ETL_3 may be faster than the deposition rate of the first electron transport layer ETL_1. The refractive index of the third electron transport layer ETL_3 may be greater than the refractive index of the first electron transport layer ETL_1.

The first electron transport layer ETL_1, the second electron transport layer ETL_2 and the third electron transport layer ETL_3 may be made of the same material but may have different refractive indexes by controlling the deposition rate. This process may be simpler than depositing each of the materials having different refractive indexes.

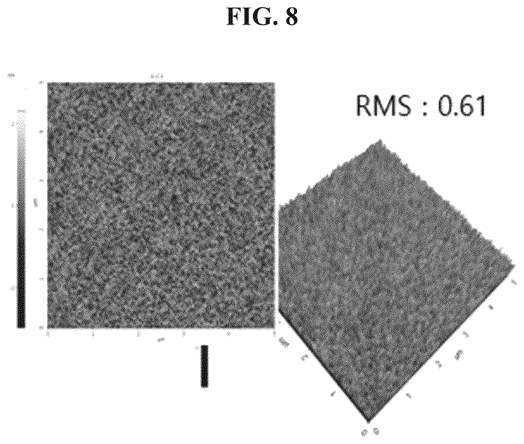

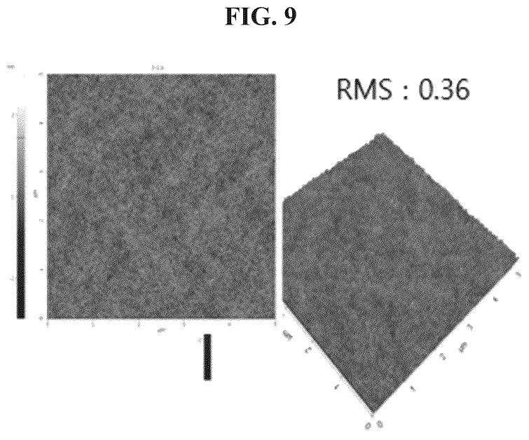

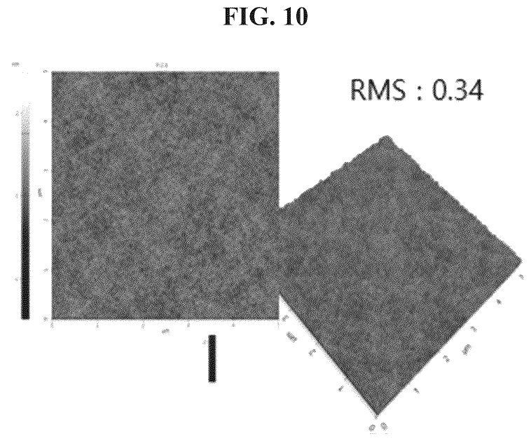

FIG. 8 is an AFM (atomic force microscope) image showing the surface roughness of an electron transport layer when deposition is carried out at the deposition rate of 0.1 Å/s according to some embodiments. FIG. 9 is an AFM (atomic force microscope) image showing the surface roughness of an electron transport layer when deposition is carried out at the deposition rate of 0.5 Å/s according to some embodiments. FIG. 10 is an AFM (atomic force microscope) image showing the surface roughness of an electron transport layer when deposition is carried out at the deposition rate of 2.5 Å/s according to some embodiments.

Referring to FIGS. 8 to 10, it can be seen that the surface roughness of the electron transport layer ETL decreases as the deposition rate increases. The process of depositing the second electron transport layer ETL_2 may be carried out at a deposition rate of 0.5 Å/s or more.

Subsequently, an electron injection layer EIL may be formed on the electron transport layer ETL (step S400). The electron injection layer EIL may be formed using the above-listed materials. A process for forming the electron injection layer EIL is not particularly limited herein.

Subsequently, a second electrode ET2 including silver (Ag) may be formed on the electron injection layer EIL, the pixel-defining layer PDL and the spacer SPC (step S500). The second electrode ET2 may be formed to entirely cover the electron injection layer EIL, the pixel-defining layer PDL and the spacer SPC.

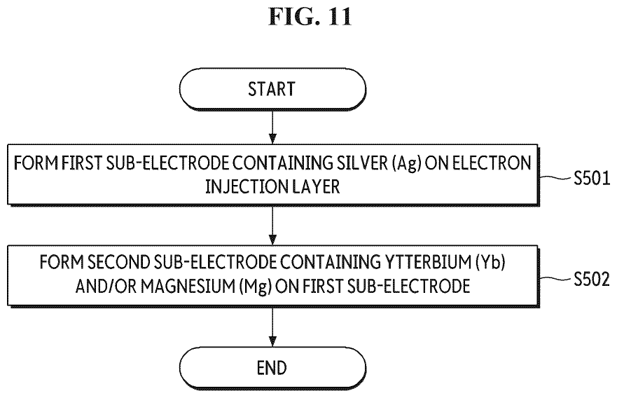

FIG. 11 is a flowchart for illustrating a method for fabricating a second electrode according to some embodiments of the present disclosure. Although FIG. 11 illustrates various operations in a method of fabricating a second electrode, according to some embodiments, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

Initially, a first sub-electrode ET2_1 containing silver (Ag) may be formed on an electron injection layer EIL, a pixel-defining layer PDL and a spacer SPC (step S501). The first sub-electrode ET2_1 may be formed by thermal deposition.

Subsequently, a second sub-electrode ET2_2 containing ytterbium (Yb) and/or magnesium (Mg) may be formed on the first sub-electrode ET2_1 (step S502). The second sub-electrode ET2_2 may be formed using the above-listed materials. The second sub-electrode ET2_2 may be formed by thermal deposition.

Subsequently, the method may further include: forming a capping layer CPL on the second sub-electrode ET2_2. The capping layer CPL may be formed using the above-listed materials. The process for forming the capping layer CPL is not particularly limited herein.

Hereinafter, the embodiments of the present disclosure will be described in more detail. It should be understood that the embodiments of the present disclosure are merely illustrative and are not intended to limit the scope of the present disclosure.

### 1. Fabrication of Light-Emitting Element

### 1) Example 1

A first electrode, a hole injection layer, a hole transport layer and an emissive layer were sequentially stacked on a substrate. A first electron transport layer (low refractive index) having the thickness of 250 Å was formed on the emissive layer at the deposition rate of 0.1 Å/s by thermal deposition. Subsequently, a second electron transport layer (low refractive index) having the thickness of 50 Å was formed on the first electron transport layer at the deposition rate of 2.5 Å/s by thermal deposition. Subsequently, ytterbium (Yb) having the thickness of 8 Å was deposited on the second electron transport layer as an electron injection layer by thermal deposition. Subsequently, silver (Ag) having the thickness of 115 Å was deposited on the electron injection layer as a second electrode by thermal deposition. Subsequently, ytterbium (Yb) and magnesium (Mg) (2:1) having the thickness of 5 Å was deposited on the second electrode as an electron transport layer by thermal deposition. Subsequently, a capping layer was formed on the second electrode to fabricate a light-emitting element.

### 2) Example 2

A light-emitting element identical to that of Example 1 was fabricated, except that a first electron transport layer (low refractive index) was formed at the deposition rate of 0.05 Å/s.

### 3) Example 3

A light-emitting element identical to that of Example 1 was fabricated, except that a first electron transport layer (low refractive index) was formed at the deposition rate of 0.01 Å/s.

### 4) Comparative Example 1

A light-emitting element identical to that of Example 1 was fabricated, except that an electron transport layer was formed to the thickness of 250 Å at the deposition rate of 3.0 Å/s and a second electrode was formed with silver (Ag) and magnesium (Mg) (10:1).

### [Evaluation]

### 1. White Light Efficiency According to Refractive Index

The refractive index of the electron transport layer and the white light efficiency of the light-emitting element of Examples 1 to 3 and Comparative Example 1 are shown in Table 1 below:

TABLE 1

| | | | | Comparative |
|---|---|---|---|---|
| | Example 1 | Example 2 | Example 3 | Example 1 |
| Refractive Index | 1.672 | 1.616 | 1.560 | 1.727 |
| of Electron | | | | |
| Transport Layer | | | | |
| White Light | 106.7 | 110.3 | 110.7 | 100 |
| Efficiency (%) | | | | |

It can be seen from Table 1 that the slower the deposition rate of the electron transport layer is, the more the refractive index of the electron transport layer decreases. When the white light efficiency of Comparative Example 1 is 100%, it can be seen that Example 1 exhibits 106.7%, Example 2 exhibits 110.3%, and Example 3 exhibits 110.7%. It can be seen that the white light efficiency increases as the refractive index of the electron transport layer decreases.

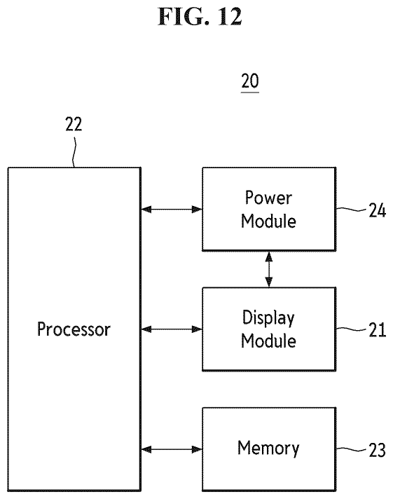

FIG. 12 is a block diagram of an electronic device according to some embodiments of the present disclosure.

Referring to FIG. 12, an electronic device 20 according to some embodiments of the present disclosure may include a display module 21, a processor 22, a memory 23, and a power module 24.

The processor 22 may include at least one of: a central processing unit (CPU), an application processor (AP), a graphic processing unit (GPU), a communication processor (CP), an image signal processor (ISP), or a controller.

The memory 23 may store data information required for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module that converts the power supplied by the power supply module to generate power required for the operation of the electronic device 20.

At least one of the elements of the electronic device 20 described above may be included in the display device 1 according to the embodiments described above. In addition, some of the individual modules functioning as a single module may be included in the display device 1 while some others may be provided separately from the display device 1. For example, the display device 1 may include the display module 21, and the processor 22, the memory 23 and the power module 24 may be provided as other devices inside the electronic device 20 than the display device 1.

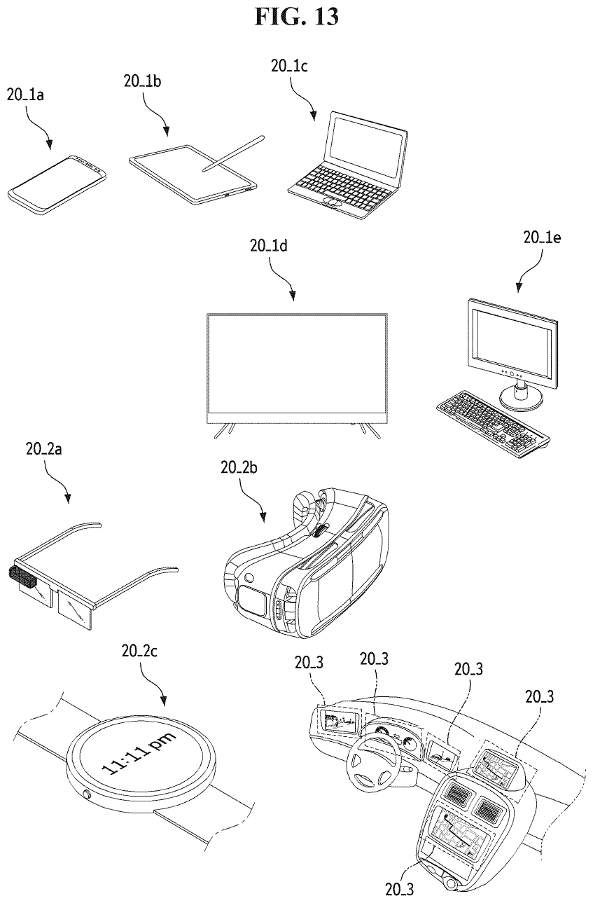

FIG. 13 is a view showing electronic devices according to a variety of embodiments of the present disclosure.

Referring to FIG. 13, a variety of electronic devices 20 employing the display devices according to the embodiments may include not only electronic devices for display images such as a smart phone 20_1a, a tablet PC 20_1b, a laptop computer 20_1c, a TV 20_1d and a desktop monitor 20_1e, but also wearable electronic devices including display modules such as smart glasses 20_2a, a head-mounted display 20_2b and a smart watch 20_2c, and electronic devices for vehicles 20_3 including display modules such as a center information display (CID) placed on the dashboard, the center fascia and the dashboard of a vehicle, and a room mirror display.

Although aspects of some embodiments of the present invention have been described with reference to the attached drawings, those skilled in the art will understand that the present invention can be implemented in other specific forms without changing the technical idea or essential features of the present invention.

Therefore, it should be understood that the embodiments described above are examples in all respects and not restrictive.

What is claimed is:

1. A display device comprising:
a substrate;
a first electrode on the substrate;
an emissive layer on the first electrode;
an electron transport layer on the emissive layer;
an electron injection layer on the electron transport layer; and
a second electrode on the electron injection layer and containing silver (Ag),
wherein the electron transport layer comprises:
a first electron transport layer; and
a second electron transport layer on a surface of the first electron transport layer,
wherein a surface of the second electron transport layer contacts the electron injection layer, and a refractive index of the second electron transport layer is greater than a refractive index of the first electron transport layer, and
wherein the second electrode comprises:
a first sub-electrode containing silver (Ag); and
a second sub-electrode located on the first sub-electrode and containing ytterbium (Yb) and/or magnesium (Mg).

2. The display device of claim 1, wherein the electron transport layer further comprises: a third electron transport layer on an opposite surface of the first electron transport layer, and
wherein a surface of the third electron transport layer contacts the emissive layer, and
wherein a refractive index of the third electron transport layer is greater than the refractive index of the first electron transport layer.

3. The display device of claim 1, wherein a surface roughness of the second electron transport layer is smaller than a surface roughness of the first electron transport layer.

4. The display device of claim 3, wherein the surface roughness of the second electron transport layer is equal to or less than 1.0 nm RMS.

5. The display device of claim 1, wherein a thickness of the electron transport layer is in a range of 5 nm to 50 nm.

6. The display device of claim 1, wherein the first electron transport layer and the second electron transport layer contain a same material.

7. The display device of claim 6, wherein a mass ratio between the first electron transport layer and the second electron transport layer is 3:1 to 50:1.

8. The display device of claim 1, further comprising:
a capping layer on the second electrode.

9. A method for fabricating a display device, the method comprising:
forming a first electrode on a substrate;
forming an emissive layer on the first electrode;
forming an electron transport layer on the emissive layer;
forming an electron injection layer on the electron transport layer; and
forming a second electrode containing silver (Ag) on the electron injection layer,
wherein the forming the electron transport layer comprises:
forming a first electron transport layer on the emissive layer; and
forming a second electron transport layer on the first electron transport layer,
wherein a deposition rate of the first electron transport layer is different from a deposition rate of the second electron transport layer, and
wherein the forming the second electrode comprises:
forming a first sub-electrode containing silver (Ag) on the electron injection layer; and
forming a second sub-electrode containing ytterbium (Yb) and/or magnesium (Mg) on the first sub-electrode.

10. The method of claim 9, wherein the deposition rate of the first electron transport layer is slower than the deposition rate of the second electron transport layer.

11. The method of claim 10, wherein a refractive index of the second electron transport layer is greater than a refractive index of the first electron transport layer.

12. The method of claim 9, wherein the second electrode is formed by thermal deposition.

13. The method of claim 9, wherein the forming the electron transport layer further comprises: prior to the forming the first electron transport layer, forming a third electron transport layer on the emissive layer,
wherein a refractive index of the third electron transport layer is greater than a refractive index of the first electron transport layer.

14. The method of claim 13, wherein the electron transport layer is formed by thermal deposition.

15. The method of claim 13, wherein the first electron transport layer, the second electron transport layer, and the third electron transport layer contain a same material.

16. The method of claim 9, wherein a surface roughness of the second electron transport layer is smaller than a surface roughness of the first electron transport layer.

17. The method of claim 16, wherein a surface roughness of the second electron transport layer is equal to or less than 1.0 nm RMS.

18. The method of claim 9, wherein a mass ratio between the first electron transport layer and the second electron transport layer is 3:1 to 50:1.

19. The method of claim 9, further comprising:
forming a capping layer on the second sub-electrode.

20. An electronic device comprising:
a display device configured to display images,
wherein the display device comprises:
a substrate;
a first electrode on the substrate;
an emissive layer on the first electrode;
an electron transport layer on the emissive layer;
an electron injection layer on the electron transport layer; and
a second electrode on the electron injection layer and containing silver (Ag),
wherein the electron transport layer comprises:
a first electron transport layer; and
a second electron transport layer on a surface of the first electron transport layer,
wherein a surface of the second electron transport layer is in contact with the electron injection layer, and a refractive index of the second electron transport layer is greater than a refractive index of the first electron transport layer, and
wherein the second electrode comprises:
a first sub-electrode containing silver (Ag); and
a second sub-electrode located on the first sub-electrode and containing ytterbium (Yb) and/or magnesium (Mg).
